(19) United States
(12) Patent Application Publication
(10) Pub. No.: US 2012/0108805 A1
(43) Pub. Date: May 3, 2012

(54) CELLULOSE-BASED RESIN COMPOSITION, MOLDED BODY AND CASE FOR ELECTRIC AND ELECTRONIC DEVICES

(75) Inventor: Yutaka Nozoe, Kanagawa (JP)

(73) Assignee: FUJIFILM CORPORATION, TOKYO (JP)

(21) Appl. No.: 13/381,242

(22) PCT Filed: Jun. 25, 2010
(86) PCT No.: PCT/JP2010/060815

§ 371 Date: Dec. 28, 2011

(30) Foreign Application Priority Data
Jun. 29, 2009 (JP) 2009-154076

(51) Int. Cl. C08B 11/193; H05K 5/00; C08J 5/00

(52) U.S. Cl. 536/90; 264/331.11; 174/50

(57) ABSTRACT

A cellulose resin composition for melt molding, containing a cellulose derivative having two or more kinds of aliphatic oxy groups having different carbon numbers (—OR) (wherein R represents an aliphatic group which may be unsubstituted or substituted), wherein a difference in carbon number between the aliphatic oxy group having the largest carbon number and the aliphatic oxy group having the smallest carbon number is 1 to 18. The cellulose resin composition can provide good thermoplasticity and excellent mechanical strength, and can be used to prepare a molded body and a case for electric and electronic devices.

### TECHNICAL FIELD

The present invention relates to a novel cellulose-based resin composition, a molded body and a case for electric and electronic devices.

### BACKGROUND ART

In members constituting electric and electronic devices such as a copy machine and a printer, various materials are used in consideration of characteristics and functions required to the members. For example, for a member (case) that accommodates a driving apparatus of an electric and electronic device or the like, and protects the driving apparatus, generally, a large amount of PC (polycarbonate), an ABS (acrylonitrile-butadiene-styrene) resin and PC/ABS are used (Patent document 1). These resins are prepared by reacting compounds obtained by using petroleum as a raw material.

However, fossil resources, such as petroleum, coal and natural gas, have carbon fixed under the earth over a long period of time as a main component. In the case where carbon dioxide is discharged into the atmosphere by combusting such fossil resources or products using the fossil resources as a raw material, carbon that does not exist in the atmosphere but is fixed deeply under the earth, is rapidly discharged as carbon dioxide, and carbon dioxide in the atmosphere is largely increased, causing global warming. Accordingly, a polymer such as ABS and PC having petroleum, which is a fossil resource, as a raw material has excellent properties as a material of the member for electric and electronic devices, but since petroleum, which is a fossil resource, is used as the raw material, it is preferable that its amount used is decreased from the standpoint of preventing global warming.

Meanwhile, a plant-derived resin is basically generated by a photosynthesis reaction using water and carbon dioxide in the atmosphere as raw materials by plants. Therefore, there is an opinion that, although carbon dioxide is generated by combusting a plant-derived resin, the carbon dioxide corresponds to carbon dioxide previously existing in the atmosphere, and thus, the balance of carbon dioxide in the atmosphere becomes zero-sum, such that the total amount of CO₂ in the atmosphere is not increased. From this opinion, the plant-derived resin is called a “carbon neutral” material. The use of the carbon neutral material instead of the petroleum-derived resin has become the pressing need for preventing the current global warming.

Therefore, in the PC polymer, there is proposed a method for decreasing petroleum-derived resources by using plant-derived resources such as starch as an alternative to a portion of the petroleum-derived raw materials (Patent document 2).

Patent document 3 discloses thermoplastic methyl hydroxypropyl cellulose ether in which an average degree of substitution of methyl groups is 1.5 to 2.9 and a mol degree of substitution (MS) of hydroxypropyl groups is 1.4 to 1.9.

Patent document 4 describes cellulose benzyl ether having thermoplasticity or biodegradability.

Patent documents 3 and 4 do not describe that a molded body is obtained by performing thermal molding by using a cellulose derivative.

### RELATED ART

### Patent Document

Patent Document 1: Japanese Patent Application Laid-Open No. Sho56-55425

Patent Document 2: Japanese Patent Application Laid-Open No. 2008-24919

Patent Document 3: Japanese Patent Application Laid-Open No. Hei4-227701

Patent Document 4: Japanese Patent Application Laid-Open No. 2000-119302

### DISCLOSURE OF INVENTION

### Problems to be Solved by the Invention

The present inventors have first conceived using cellulose as a carbon-neutral resin. Generally, however, since cellulose does not have thermoplasticity, it is difficult to perform melt molding by heating, and therefore, it is not suitable for melt molding processing. Further, although thermoplasticity can be provided, mechanical strength (particularly, toughness and rigidity) is insufficient.

Therefore, the object of the present invention is to provide a cellulose resin composition that has good thermoplasticity and excellent mechanical strength, and a molded body and a case for an electric and electronic device using the same.

### Means for Solving the Problems

The present inventors found out, in consideration of a molecular structure of cellulose, that good thermoplasticity and mechanical strength are exhibited when using a cellulose derivative having a specific structure as the cellulose, thereby accomplishing the present invention.

That is, the above object may be accomplished by the following means.

[1]

A cellulose resin composition for melt molding, containing a cellulose derivative having two or more kinds of aliphatic oxy groups having different carbon numbers (—OR), wherein R represents an aliphatic group which may be unsubstituted or substituted, a difference in carbon number between the aliphatic oxy group having the largest carbon number and the aliphatic oxy group having the smallest carbon number is 1 to 18.

[2]

The cellulose derivative has two kinds of aliphatic oxy groups having different carbon numbers (—OR1 and —OR2) (the cellulose resin composition as described in [1], wherein R1 and R2 represent an aliphatic group which may be unsubstituted or substituted. Provided that, a difference in carbon number between R1 and R2 is 1 to 18).

[3]

The cellulose resin composition as described in [2], wherein the degree of substitution (DS_{B}) of the aliphatic oxy group (—OR1) is 1.5 to 2.8, and the degree of substitution (DS_{C}) of the aliphatic oxy group (—OR2) is 0.1 to 0.8.

(wherein DS_{B} represents the number of aliphatic oxy groups (—OR1) with respect to the hydroxyl groups at the 2-, 3- and 6-positions of a β-glucose ring in the repeating unit, and DS_{C} represents the number of aliphatic oxy groups (—OR2) with respect to the hydroxyl groups at the 2-, 3-, and 6-positions of a cellulose structure of the β-glucose ring in the repeating unit).

[4]

The cellulose resin composition as described in any one of [1] to [3], wherein the difference in carbon number is 1 to 10.

[5]

The cellulose resin composition as described in any one of [1] to [3], wherein the difference in carbon number is 5 to 7.

[6]

The cellulose resin composition as described in any one of [1] to [5], wherein R, R1 and R2 do not contain a hydrogen bonding group and an aromatic group.

[7]

The cellulose resin composition as described in any one of [2] to [6], wherein the carbon number of R1 is 1 to 6, and the carbon number of R2 is 1 to 18.

[8]

The cellulose resin composition as described in any one of [2] to [7], wherein R1 is an ethyl group.

[9]

The cellulose resin composition as described in any one of [2] to [7], wherein R1 is an ethyl group, and R2 is an octyl group.

[10]

A molded body obtained by melt molding the cellulose resin composition as described in any one of [1] to [9].

[11]

A case for electric and electronic devices constituted by the molded body as described in [10].

[12]

A cellulose derivative having an ethoxy group (—OC₂H₅) and an octyloxy group (—OC₈H₁₇).

[13]

A method for preparing a cellulose derivative having two or more kinds of aliphatic oxy groups having different carbon numbers (—OR) (wherein R represents an aliphatic group which may be unsubstituted substituted), in which a difference in carbon number between the aliphatic oxy group having the largest carbon number and the aliphatic oxy group having the smallest carbon number is 1 to 18, the method including reacting cellulose and two or more kinds of halogenated aliphatic compounds having different carbon numbers in the presence of a base.

[14]

A method for manufacturing a molded body, including heating and molding the cellulose resin composition as described in any one of [1] to [9] or the cellulose derivative as described in [12].

### Effects of the Invention

According to the cellulose resin composition for melt molding of the present invention, it is possible to obtain a molded body that has excellent toughness (impact strength) and rigidity (bending elasticity, and bending strength) while good thermoplasticity is maintained. Further, since the cellulose derivative of the present invention can be synthesized in one pot from cellulose, it is possible to provide a material for melt molding having the aforementioned excellent performance at a low cost. In addition, since the derivative is a plant-derived resin, it can replace a conventional petroleum-derived resin as a material that can contribute to preventing global warming. Therefore, the cellulose resin composition for melt molding of the present invention may be suitably used, for example, as a case for electric and electronic devices.

### EMBODIMENTS FOR CARRYING OUT THE INVENTION

A cellulose resin composition for melt molding of the present invention contains a cellulose derivative having two or more kinds of aliphatic oxy groups having different carbon numbers (—OR) (wherein R represents an aliphatic group which may be unsubstituted or substituted), wherein a difference in carbon number between the aliphatic oxy group having the largest carbon number and the aliphatic oxy group having the smallest carbon number is 1 to 18.

Hereinafter, the present invention will be described in detail.

1. Cellulose Derivative

The cellulose derivative of the present invention has two or more kinds of aliphatic oxy groups having different carbon numbers (—OR) (wherein R represents an aliphatic group which may be unsubstituted or substituted).

That is, the cellulose derivative of the present invention is obtained by substituting at least a portion of the hydroxyl groups contained in cellulose (C₆H₁₀O₅)ₙ with two or more kinds of aliphatic oxy groups having different carbon numbers (—OR).

Herein, “cellulose” means a polymer compound which is obtained by polymerizing a plurality of glucoses by a β-1,4-glucoside bond, in which the hydroxyl group bonded to carbon atoms at the 2-, 3- and 6-positions of the glucose ring of cellulose is unsubstituted. Further, the “hydroxyl groups contained in cellulose” refers to hydroxyl groups bonded to the carbon atoms at the 2-, 3- and 6-positions of the glucose ring of cellulose.

In more detail, the cellulose derivative of the present invention has a repeating unit represented by the following Formula (1):

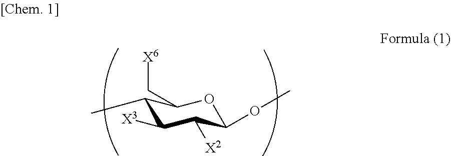

In Formula (1), each of X², X³ and X⁶ independently represents a hydroxyl group or other substituents. However, at least a portion of X², X³ and X⁶ is substituted with two or more kinds of aliphatic oxy groups having different carbon numbers (—OR).

In a plurality of repeating units contained in the cellulose derivative, each of X², X³ and X⁶ may be the same as or different from every other X², X³ and X⁶.

Further, since the substitution by the aliphatic oxy group (—OR) may be a portion of X², X³ and X⁶, X², X³ and X⁶ that are not the aliphatic oxy groups may be hydroxyl groups or other substituent groups.

As described above, the cellulose derivative of the present invention may exhibit thermoplasticity, be suitable for melt molding processing, and easily provide a molded body, due to substituting at least a portion of the hydroxyl groups of the β-glucose ring with two or more kinds of aliphatic oxy groups having different carbon numbers (—OR). Moreover, since the molded body formed by using the cellulose derivative can make toughness (impact strength) and rigidity (bending elasticity and bending strength) compatible, the molded body has excellent mechanical strength. Further, since the cellulose derivative has the same kind of functional groups which are aliphatic oxy groups, the derivative can be synthesized in one pot from cellulose, and a melt molding material having excellent performance may be provided at a low cost. Moreover, since cellulose is a component that is completely derived from plants, cellulose is carbon-neutral, and may largely decrease a load to the environment.

The cellulose derivative of the present invention may contain two or more kinds of aliphatic oxy groups having different carbon numbers at any portions of hydroxyl groups contained in cellulose, may be formed of the same repeating unit, or may be formed of a plurality of kinds of repeating units. Further, the cellulose derivative of the present invention does not need to contain all of the two or more kinds of aliphatic oxy groups in one repeating unit.

As a more detailed aspect, there may be the following aspect, for example, in the case where there are two kinds of aliphatic oxy groups in the cellulose derivative. (1) A cellulose derivative which is constituted by a repeating unit in which a portion of X², X³ and X⁶ is substituted with an aliphatic oxy group (—ORa) with a certain carbon number, and a repeating unit in which a portion of X², X³ and X⁶ is substituted with an aliphatic oxy group (—ORb) with a different carbon number from —ORa. (2) A cellulose derivative which is constituted by the same kind of repeating unit in which any one of X², X³ and X⁶ in one repeating unit is substituted with both of —ORa and —ORb (that is, the one repeating unit has both of —ORa and —ORb). (3) A cellulose derivative in which repeating units having different substitution positions or kinds of substituent group are randomly bonded.

Further, in a portion of the cellulose derivative, an unsubstituted repeating unit (that is, in Formula (1), the repeating unit in which all of X², X³ and X⁶ are a hydroxyl group) may be contained.

In two or more kinds of aliphatic oxy groups having different carbon numbers (—OR), the aliphatic group R is not particularly limited, and may include, for example, an alkyl group, a cycloalkyl group, an alkenyl group and an alkynyl group. Further, the aliphatic group may be any one of a straight chain, a branched chain and a cycle, and may have an unsaturated bond.

The carbon number of the aliphatic group R is not particularly limited, but for example, may be 1 to 30, and preferably 1 to 20.

In two or more kinds of aliphatic oxy groups having different carbon numbers (—OR), a difference in carbon number between the aliphatic oxy group having the largest carbon number and the aliphatic oxy group having the smallest carbon number is 1 to 18. The difference in carbon number is preferably 1 to 10, more preferably 5 to 7, and most preferably 6. By setting the difference in carbon number to the range of 1 to 18, it is possible to provide a melt molding material having excellent thermoplasticity and mechanical strength.

Two or more kinds of aliphatic oxy groups having different carbon numbers are preferably two kinds of aliphatic oxy groups. That is, the cellulose derivative of the present invention preferably has two kinds of aliphatic oxy groups having different carbon numbers (—OR1 and —OR2) (wherein R1 and R2 represent aliphatic groups which may be unsubstituted or substituted. Provided that, the difference in carbon number between R1 and R2 is 1 to 18).

The preferable difference in carbon number is the same as the case where two or more kinds of aliphatic oxy groups are contained. That is, the difference in carbon number between R1 and R2 is preferably 1 to 10, more preferably 5 to 7, and most preferably 6.

The carbon number of R1 and R2 is preferably 1 to 30, and more preferably 1 to 20.

Further, the carbon number of one aliphatic group R1 is preferably 1 to 6, more preferably 1 to 4, and much more preferably 1 or 2. In addition, the carbon number of the other aliphatic group R2 is preferably 1 to 18, more preferably 4 to 12, and much more preferably 6 to 9. By setting the carbon number of R1 to 1 to 6, and the carbon number of R2 to 1 to 18, it is possible to obtain the cellulose derivative that can be molded at a low temperature and have high mechanical strength.

R1 and R2 are preferably an alkyl group having a straight chain or branched chain, and more preferably a straight chain type alkyl group. Since R1 and R2 are the straight chain type alkyl group, mechanical strength (particularly, rigidity) may be more excellent.

The alkyl group may include a methyl group, an ethyl group, a propyl group, a butyl group, a pentyl group, a hexyl group, a heptyl group, an octyl group, a dodecyl group, an octadecyl group, a 2-ethylhexyl group, a nonyl group, an isopropyl group, an isobutyl group, a tert-butyl group and an isoheptyl group.

More preferably, R1 is a methyl group or ethyl group, and much more preferably, R1 is an ethyl group. When R1 is a methyl group or ethyl group, mechanical strength is more excellent.

Further, in the case where R1 is an ethyl group, R2 is preferably an alkyl group having the carbon number of 7 to 9, more preferably an alkyl group having the carbon number of 8 (for example, a 2-ethylhexyl group or an octyl group), and much more preferably, R1 is an ethyl group and R2 is an octyl group.

The cellulose derivative in which R1 is an ethyl group and R2 is an octyl group, that is, the cellulose derivative having an ethoxy group (—OC₂H₅) and an octyloxy group (—OC₈H₁₇) is a novel compound, has very excellent thermoplasticity and mechanical strength (particularly, toughness), and is particularly useful as a melt molding material.

The aliphatic group represented by R, R1 and R2 may be unsubstituted or substituted, but preferably may be unsubstituted.

In the case where the aliphatic group represented by R, R1 and R2 has a substituent, it is preferable that the substituent does not contain a hydrogen bonding group (a hydroxyl group and an amide group) and an aromatic group. Since R, R1 and R2 do not contain a hydrogen bonding group, it is possible to obtain a cellulose derivative having excellent thermally molding property. Further, since R, R1, and R2 do not contain the aromatic group, toughness (impact rigidity) is excellent.

In the case where the aliphatic group represented by R, R1, and R2 has a substituent, the substituent may include particularly a halogen atom (for example, a fluorine atom, a chlorine atom, a bromine atom and an iodine atom), an alkoxy group (which the carbon number of the alkyl group moiety is preferably 1 to 5) and an alkenyl group. Further, in the case where the aliphatic group represented by R, R1 and R2 is not an alkyl group, the aliphatic group may have an alkyl group (preferably carbon number of 1 to 5) as a substituent.

The substitution position of two kinds of aliphatic oxy groups (—OR1 and —OR2) of the cellulose derivative and the number (degree of substitution) of aliphatic oxy groups (—OR1 and —OR2) per β-glucose ring unit are not particularly limited.

For example, the degree of substitution (DS_{B}) of the aliphatic oxy group (—OR1) (number of the aliphatic oxy groups (—OR1) with respect to the hydroxyl group at the 2-, 3-, and 6-positions of the β-glucose ring in the repeating unit) may be generally 1.0 or higher, and preferably 1.5 to 2.8. By setting DS_{B} within this range, the thermal molding property may be excellent.

Further, the degree of substitution (DS_{C}) of the aliphatic oxy group (—OR2) (number of the aliphatic oxy groups (—OR2) with respect to the hydroxyl group at the 2-, 3-, and 6-positions of the cellulose structure of the β-glucose ring in the repeating unit) may be generally 0.05 or higher, preferably 0.1 or higher, and more preferably 0.1 to 0.8.

By setting DS_{C} within this range, mechanical strength may be excellent.

Further, the number of unsubstituted hydroxyl groups existing in the cellulose derivative is not particularly limited.

The degree of substitution (DS_{A}) of the hydroxyl group (a ratio of the unsubstituted hydroxyl group at the 2-, 3-, and 6-positions in the repeating unit) may be generally 0.01 to 1.5, and preferably 0.2 to 1.2. By setting DS_{A} to 0.01 or higher, fluidity of the resin composition may be improved. Further, by setting DS_{A} to 1.5 or lower, the fluidity of the resin composition may be improved, or foaming by absorption of the resin composition may be suppressed in acceleration and molding of thermal decomposition.

In addition, the sum of the degrees of substitution (DS_{A}+DS_{B}+DS_{C}) is 3.

In the molecular weight of the cellulose derivative, the number average molecular weight (Mn) is preferably 5,000 to 500,000, much more preferably 10,000 to 300,000, and most preferably 20,000 to 200,000. Further, the weight average molecular weight (Mw) is preferably 10,000 to 3,000,000, much more preferably 50,000 to 2,000,000, and most preferably 100,000 to 1,500,000. The molecular weight distribution (MWD) is preferably 1.1 to 5.0, and much more preferably 1.5 to 3.5. By setting the average molecular weight to the above range, molding property and dynamic strength of the molded body may be improved. In addition, by setting the molecular weight distribution to this range, the molding property may be improved.

The number average molecular weight (Mn), the weight average molecular weight (Mw) and the molecular weight distribution (MWD) may be measured by using a gel permeation chromatography (GPC). Specifically, tetrahydrofurane may be used as a solvent, a polystyrene gel may be used, the number average molecular weight (Mn), the weight average molecular weight (Mw), and the molecular weight distribution (MWD) may be obtained by using a reduced molecular weight calibration curve previously obtained from a standard monodispersion polystyrene constitution curve.

Further, the cellulose derivative of the present invention may have other substituents which are not mentioned above.

2. Preparation of the Cellulose Derivative

The method for preparing the cellulose derivative of the present invention is not particularly limited, and may be prepared by using cellulose as a raw material, and substituting at least a portion of the hydroxyl groups contained in cellulose with two or more kinds of halogenated aliphatic compounds having different carbon numbers (that is, etherification).

The etherification of cellulose is preferably performed by reacting a halogenated aliphatic compound with cellulose.

The raw material of cellulose is not particularly limited, and, for example, cotton, linter, pulp and the like may be used.

The halogenated aliphatic compound is not particularly limited, and as the halogen atom moiety of the halogenated aliphatic compound, chlorine, bromine and iodine are used. Further, the aliphatic group moiety of the halogenated aliphatic compound may be the same as R1 and R2. That is, for example, in the case where R1 and R2 are an alkyl group, halogenated alkyl is reacted.

A method for introducing two kinds of aliphatic oxy groups into cellulose is not particularly limited, and may include, for example, a method for reacting at least two kinds of halogenated aliphatic compounds and cellulose, or a method for reacting known cellulose ether such as methylcellulose or ethylcellulose and the halogenated aliphatic compound, and any one may be used. In the former case, since the cellulose derivative can be synthesized in one pot from cellulose, it is advantageous in that the derivative can be prepared at a low cost.

Further, in the reaction of cellulose or cellulose ether and the halogenated aliphatic compound, the reaction may be performed in the presence of a base. As the base, strong alkali such as sodium hydroxide may be used.

The method for preparing a cellulose derivative according to the present invention is a method for preparing a cellulose derivative having two or more kinds of aliphatic oxy groups having different carbon numbers (—OR) (wherein R represents an aliphatic group which may be unsubstituted or substituted), wherein a difference in carbon number between the aliphatic oxy group having the largest carbon number and the aliphatic oxy group having the smallest carbon number is 1 to 18, and includes a process for reacting a cellulose and two or more kinds halogenated aliphatic compounds having different carbon numbers in the presence of a base.

Other detailed preparation conditions may be set according to a general method. For example, a method described on pages 131 to 164 of “Dictionary of Cellulose” (Asakura Bookstore, 2000) may be referred.

3. Resin Composition Containing the Cellulose Derivative and Molded Body

The cellulose resin composition for melt molding of the present invention includes the cellulose derivative having two or more kinds of aliphatic oxy groups having different carbon numbers, and if necessary, may further include other additives.

The content of the component contained in the resin composition is not particularly limited. The content of the cellulose derivative is preferably 75 weight % or higher, more preferably 80 weight % or higher, and much more preferably 80 to 100 weight %.

The resin composition of the present invention may include various additives such as a filler and a flame retardant, if necessary, in addition to the cellulose derivative of the present invention.

The resin composition of the present invention may contain a filler (reinforcing material). By containing a filler, mechanical properties of the molded body formed by the resin composition may be reinforced.

As a filler, a known matter may be used. The shape of the filler may be any one of a fiber type, a plate type, a particle type, and a powder type. Further, the filler may be an inorganic material or an organic material.

In detail, the inorganic filler may include a fiber type inorganic filler such as glass fiber, carbon fiber, graphite fiber, metal fiber, potassium titanate whisker, aluminum borate whisker, magnesium-based whisker, silicon-based whisker, wollastonite, sepiolite, slag fiber, zonolite, ellestadite, gypsum fiber, silica fiber, silica-alumina fiber, zirconia fiber, boron nitride fiber, silicon nitride fiber and boron fiber; and a plate type or particle type inorganic filler such as glass flake, non-swelling mica, carbon black, graphite, metal foil, ceramic bead, talc, clay, mica, sericite, zeolite, bentonite, dolomite, kaolin, fine silicate, feldspar sand, potassium titanate, shirasu balloon, calcium carbonate, magnesium carbonate, barium sulfate, calcium oxide, aluminum oxide, titanium oxide, magnesium oxide, aluminum silicate, silicon oxide, aluminum hydroxide, magnesium hydroxide, gypsum, novaculite, dawsonite and white clay.

The organic filler may include synthetic fiber such as polyester fiber, nylon fiber, acryl fiber, regenerated cellulose fiber, and acetate fiber, natural fiber such as kenaf, ramie, cotton, jute, hemp, sisal, Manila hemp, flax, linen, silk and wool, a fiber type organic filler obtained from microcrystalline cellulose, sugar, wood pulp, tissues and waste paper, or a particle type organic filler such as an organic pigment.

In the case where the resin composition contains a filler, the content thereof is not limited, but the content may be generally 30 parts by weight or lower, and preferably 5 to 10 parts by weight based on 100 parts by weight of the cellulose derivative.

The resin composition of the present invention may contain a flame retardant. By this, a flame retardant effect may be improved, which decreases or suppresses a combustion speed.

The flame retardant is not particularly limited, and may be one commercially available. For example, a bromine-based flame retardant, a chlorine-based flame retardant, a phosphorus-containing flame retardant, a silicon-containing flame retardant, a nitrogen compound-based flame retardant and an inorganic-based flame retardant may be used. Among them, the phosphorus-containing flame retardant and silicon-containing flame retardant are preferable, because corrosion of processing machines or molds, or deterioration of operation environments are not caused by the halogenated hydrogen generated by thermal decomposition when compositing with the resin or molding processing, and also, it is unlikely that the environment would be negatively affected by harmful materials such as dioxines generated by dispersing or decomposing halogen gas during incineration and discarding.

The phosphorus-containing flame retardant is not particularly limited, and may be one commercially available. For example, an organic phosphorus-based compound such as phosphate ester, condensed phosphate ester and polyphosphate may be used.

Particular examples of phosphate ester may include trimethyl phosphate, triethyl phosphate, tributyl phosphate, tri(2-ethylhexyl)phosphate, tributoxyethyl phosphate, triphenyl phosphate, tricredyl phosphate, trixylenyl phosphate, tris(isopropylphenyl)phosphate, tris(phenylphenyl)phosphate, trinaphthyl phosphate, credyldiphenyl phosphate, xylenyldiphenyl phosphate, diphenyl(2-ethylhexyl)phosphate, di(isopropylphenyl)phenylphosphate, monoisodecyl phosphate, 2-acryloyloxyethyl acid phosphate, 2-methacryloyloxyethyl acid phosphate, diphenyl-2-acryloyloxyethyl phosphate, diphenyl-2-methacryloyloxyethyl phosphate, melamine phosphate, dimelamine phosphate, melamine pyrrophosphate, triphenyl phosphine oxide, tricredyl phosphine oxide, diphenyl methane phosphonate and diethyl phenylphosphonate.

Condensed phosphate ester may include, for example, aromatic condensed phosphate ester such as resorcinol polyphenylphosphate, resorcinol poly(di-2,6-xylyl)phosphate, bisphenol A polycredylphosphate, hydroquinone poly(2,6-xylyl)phosphate, and a condensate thereof.

Further, a phosphoric acid, polyphosphoric acid and a metal of Groups 1 to 14 of the periodic table, ammonia, aliphatic amine and polyphosphate formed of salts of aromatic amine may be exemplified. The representative salt of polyphosphate may include a metal salt such as lithium salt, sodium salt, calcium salt, barium salt, iron(II) salt, iron(III) salt and aluminum salt, aliphatic amine salt such as methylamine salt, ethylamine salt, diethylamine salt, triethylamine salt, ethylenediamine salt and piperazine salt, and aromatic amine salt such as pyridine salt and triazine.

In addition to the above, halogen-containing phosphate ester such as trischloroethylphosphate, trisdichloropropylphosphate and tris(β-chloropropyl)phosphate), a phosphazene compound having a structure in which a phosphorus atom and a nitrogen atom are linked by a double bond, and phosphate ester amide may be exemplified.

The phosphorus-containing flame retardants may be used either alone or in combination of two or more species.

The silicon-containing flame retardant may include an organic silicon compound having a two or three dimensional structure, a compound in which a methyl group of a side chain or a terminal of polydimethylsiloxane or polydimethylsiloxane is substituted or modified by a hydrogen atom, a substituted or unsubstituted aliphatic hydrocarbon group, an aromatic hydrocarbon group, so-called silicone oil or modified silicone oil.

The substituted or unsubstituted aliphatic hydrocarbon group and aromatic hydrocarbon group may include, for example, an alkyl group, a cycloalkyl group, a phenyl group, a benzyl group, an amino group, an epoxy group, a polyether group, a carboxyl group, a mercapto group, a chloroalkyl group, an alkyl higher alcohol ester group, an alcohol group, an aralkyl group, a vinyl group or a trifluoromethyl group.

The silicon-containing flame retardants may be used either alone or in combination of two or more species.

Further, as a flame retardant other than the phosphorus-containing flame retardant or silicon-containing flame retardant, for example, there may be an inorganic-based flame retardant such as magnesium hydroxide, aluminum hydroxide, antimony trioxide, antimony pentoxide, sodium antimonate, zinc hydroxystannate, zinc stannate, metastannic acid, tin oxide, tin oxide salt, zinc sulfate, zinc oxide, ferrous oxide, ferric oxide, stannic oxide, zinc borate, ammonium borate, ammonium octamolybdate, metal salt of tungsten acid, complex oxide of tungsten and metaroid, ammonium sulfaminate, ammonium bromide, a zirconium-based compound, a guanidine-based compound, a fluorine-based compound, graphite and swelling graphite. The other flame retardants may be used either alone or in combination of two or more species.

In the case where the resin composition of the present invention contains a flame retardant, the content thereof is not limited, but the content may be generally 30 parts by weight or lower, and preferably 2 to 10 parts by weight based on 100 parts by weight of the cellulose derivative. By setting the content to the above range, it is possible to improve impact resistance and brittleness, or to suppress occurrence of pellet blocking.

The resin composition of the present invention may include other components for the purpose of further improving various properties such as moldability and flame retardancy within a scope in which the object of the present invention is not hindered, in addition to the cellulose derivative, filler and flame retardant.

The other components may include, for example, a polymer other than the cellulose derivative, a plasticizer, a stabilizer (antioxidant and UV absorbing agent), a release agent (fatty acid, fatty acid metal salt, oxy fatty acid, fatty acid ester, aliphatic partially saponificated ester, paraffin, low molecular weight polyolefine, fatty acid amide, alkylene-bis fatty acid amide, aliphatic ketone, fatty acid lower alcohol ester, fatty acid polyvalent alcohol ester, fatty acid polyglycol ester and modified silicone), an antistatic agent, a flame retardant agent, a processing agent, a drip inhibitor, an antimicrobial and an anti-fungal agent. Further, a coloring agent including a dye or pigment may be added.

As the polymer other than the cellulose derivative, a thermoplastic polymer or a thermosetting polymer may be used, but the thermoplastic polymer is preferable from the standpoint of moldability. Particular examples of the polymer other than the cellulose derivative may include polyolefin such as low density polyethylene, straight chain type low density polyethylene, high density polyethylene, polypropylene, ethylene-propylene copolymer, ethylene-propylene-non-conjugated diene copolymer, ethylene-butene-1 copolymer, polypropylene homopolymer, polypropylene copolymer(ethylene-propylene block copolymer), polybutene-1 and poly-4-methylpentene-1; polyester such as polybutylene terephthalate, polyethylene terephthalate and other aromatic polyester; polyamide such as nylon 6, nylon 46, nylon 66, nylon 610, nylon 612, nylon 6T and nylon 12; an acryl resin such as polystyrene, high impact polystyrene, polyacetal (including homopolymer and copolymer), polyurethane, aromatic and aliphatic polyketone, polyphenylene sulfide, polyether ether ketone, thermoplastic starch resin, methyl polymethacylate or methacylic ester-acrylic ester copolymer; thermoplastic polyimide such as AS resin (acrylonitrilestyrene copolymer), ABS resin, AES resin (ethylene-based rubber reinforced AS resin), ACS resin (chlorinated polyethylene reinforced AS resin), ASA resin (acryl-based rubber reinforced AS resin), polyvinyl chloride, polyvinylidene chloride, vinyl ester-based resin, maleic anhydride-styrene copolymer, MS resin (methyl methacylate-styrene copolymer), polycarbonate, polyarylate, polysulfone, polyether sulfone, phenoxy resin, polyphenylene ether, modified polyphenylene ether and polyether imide; a fluorine-based polymer such as polytetrafluoroethylene, tetrafluoroethylene-hexafluoropropylene copolymer, tetrafluoroethylene-ethylene copolymer, tetrafluoroethylene-perfluoroalkyl vinyl ether copolymer, polychlorotrifluoroethylene, polyvinylidene fluoride and tetrafluoroethylene-hexafluoropropylene-perfluoroalkyl vinyl ether copolymer; cellulose acetate; polyvinyl alcohol; unsaturated polyester; melamine resin; phenol resin; urea resin and polyimide.

Further, there may be various thermoplastic elastomers such as various acryl rubber, ethylene-vinyl acetate copolymer, ethylene-acrylic acid copolymer and alkali metal salt thereof (so-called ionomer), ethylene-alkylester acrylate copolymer (for example, ethylene-ethyl acrylate copolymer, and ethylene-butyl acrylate copolymer), diene-based rubber (for example, 1,4-polybutadiene, 1,2-polybutadiene, polyisoprene and polychloroprene), a copolymer of diene and vinyl monomer (for example, styrene-butadiene random copolymer, styrene-butadiene block copolymer, styrene-butadiene-styrene block copolymer, styrene-isoprene random copolymer, styrene-isoprene block copolymer, styrene-isoprene-styrene block copolymer, a copolymer in which styrene is graft copolymerized with polybutadiene, and butadiene-acrylonitrile copolymer), polyisobutylene, copolymer of isobutylene and butadiene or isoprene, butyl rubber, natural rubber, thiokol rubber, polysulfide rubber, acryl rubber, nitrile rubber, polyether rubber, epichlorohydrin rubber, fluorine rubber, silicone rubber, other polyurethanes or polyesters and polyamides.

In addition, a polymer having various degrees of crosslinking, a polymer having various microstructures, for example, a cis structure and a trans structure, a matter having a vinyl group, a polymer having various average particle diameters (in the resin composition), a multilayered structure polymer that is called a core-shell rubber constituted by a core layer, one or more shell layers covering the core layer and the adjacent layers formed of different polymers and core-shell rubber including a silicone compound may be used.

These polymers may be used either alone or in combination of two or more species.

In the case where the resin composition of the present invention contains a polymer other than the cellulose derivative, the content thereof is preferably 30 parts by weight or lower and more preferably 2 to 10 parts by weight based on 100 parts by weight of the cellulose derivative.

The resin composition of the present invention may contain the plasticizer. Therefore, flame retardancy and moldability may be further improved. As the plasticizer, a matter that is used in molding of the polymer may be used. For example, there may be a polyester-based plasticizer, a glycerin-based plasticizer, a polyvalent ester carboxylate-based plasticizer, a polyalkyleneglycol-based plasticizer and an epoxy-based plasticizer.

Particular examples of the polyester-based plasticizer may include polyester that is formed of an acid component such as adipic acid, sebacic acid, terephthalic acid, isophthalic acid, naphthalene dicarboxylate, diphenyldicarboxylate and rosin, and a diol component such as propyleneglycol, 1,3-butanediol, 1,4-butanediol, 1,6-hexanediol, ethyleneglycol and diethyleneglycol, or polyester that is formed of hydroxy carboxylate such as polycaprolactone. Those polyesters may be terminally capped with a monofunctional carboxylic acid or monofunctional alcohol, or may be terminally capped with an epoxy compound.

Particular examples of the glycerin-based plasticizer may include glycerin monoacetomonolaulate, glycerin diacetomonolaulate, glycerin monoacetomonostearate, glycerin diacetomonooleate and glycerin monoacetomonomontanate.

Particular examples of the polyvalent carboxylic acid-based plasticizer may include phthalic ester such as dimethyl phthalate, diethyl phthalate, dibutyl phthalate, dioctyl phthalate, diheptyl phthalate, dibenzyl phthalate and butylbenzyl phthalate, trimelitic ester such as tributyl trimelitate, trioctyl trimelitate and trihexyl trimelitate, adipic ester such as diisodecyl adipate, n-octyl-n-decyl adipate, methyl diglycol butyl diglycol adipate, benzyl methyl diglycol adipate and benzyl butyl diglycol adipate, citric ester such as triethyl acetylcitrate and tributyl acetylcitrate, azelic ester such as di-2-ethylhexyl azelate, dibutyl cebacate and di-2-ethylhexyl cebacate.

Particular examples of the polyalkyleneglycol-based plasticizer may include polyalkylene glycol such as polyethylene glycol, polypropylene glycol, poly(ethylene oxide.propylene oxide)block and/or random copolymer, polytetramethylene glycol, ethylene oxide-added polymer of bisphenols, propylene oxide-added polymer of bisphenols, and tetrahydrofurane-added polymer of bisphenols, or a terminal-epoxy modified compound thereof, a terminal-ester modified compound thereof and a terminal-ether modified compound thereof.

The epoxy-based plasticizer generally represents epoxytriglyceride that is formed of alkyl epoxystearate and soybean oil, but in addition to this, a so-called epoxy resin mainly having bisphenol A and epichlorohydrine as a raw material may be also used.

Particular examples of the other plasticizers may include benzoic ester of aliphatic polyol such as neopentyl glycol dibenzoate, diethylene glycol dibenzoate and triethylene glycol di-2-ethylbutylate, fatty acid amide such as stearic amine, aliphatic carboxylic ester such as butyl oleate, oxylic ester such as methyl acetylricinoleate and butyl acetylricinoleate, pentaerythritol, and various sorbitols.

In the case where the resin composition of the present invention contains a plasticizer, the content thereof is generally 5 parts by weight or lower, preferably 0.005 to 5 parts by weight, and more preferably 0.01 to 1 parts by weight on the basis of 100 parts by weight of the cellulose derivative.

The molded body of the present invention is obtained by molding the resin composition containing the cellulose derivative. In more detail, the molded body is obtained by a manufacturing method including a process for heating and molding the resin composition containing the cellulose derivative and, if necessary, various additives.

The molding method may include, for example, injection molding, extrusion molding and blow molding.

The heating temperature is preferably 160 to 300° C. and more preferably 180 to 260° C.

The use of the molded body of the present invention is not particularly not limited, but may be used as, for example, interior or exterior parts of electric and electronic devices (devices for home appliances, OA media related devices, optical devices, communication devices and the like), and materials for automobiles, machinery parts, and housing and construction. Among the materials, from the standpoint of excellent heat resistance, impact resistance and a low load to the environment, for example, the molded body may be suitably used as exterior parts (particularly, case) for electric and electronic devices such as copiers, printers, personal computers and televisions.

### EXAMPLE

The present invention will be described with reference to the following Examples and Comparative Examples, but the scope of the present invention is not limited to the following Examples.

### Synthetic Example 1

### Synthesis of P-1

150 g of ethylcellulose (manufactured by Dow Chemical, Co., Ltd., trademark: Ethocel, degree of ethoxy substitution 2.6), and 450 mL of 50% sodium hydroxide aqueous solution were placed into a 5 L three-neck flask equipped with a mechanical stirrer, a thermocouple, a cooling tube and a drop lot, and followed by stirring at 45° C. for 1 hour. Further, 120 mL of iodomethane (3 mol equivalent based on the glucopyranose unit) and 150 mL of toluene were added, and followed by stirring at the external temperature of 75° C. for 5 hours. After the temperature was cooled to room temperature, an off-white solid was obtained by vigorously stirring in 4 L of water. The obtained off-white solid was re-dispersed in 2 L of methanol, and 6 L of water was further added, followed by vigorously stirring. This operation was repeated three times to obtain a white solid. The obtained white solid was separated by suction filtration, and dried under vacuum at 100° C. for 6 hours to obtain the desired cellulose derivative (P-1, the degree of substitution, the molecular weight and the glass transition temperature are described in Table 1) as a white powder (112 g).

### Synthetic Example 2

### Synthesis of P-2

In the same manner as in Synthetic Example 1 except that iodomethane was replaced with butyl bromide, the desired cellulose derivative (P-2, the degree of substitution, the molecular weight and the glass transition temperature are described in Table 1) was obtained as a white powder (100 g).

### Synthetic Example 3

### Synthesis of P-3

In the same manner as in Synthetic Example 1 except that iodomethane was replaced with heptyl bromide, the desired cellulose derivative (P-3, the degree of substitution, the molecular weight and the glass transition temperature are described in Table 1) was obtained as a white powder (88 g).

### Synthetic Example 4

### Synthesis of P-4

In the same manner as in Synthetic Example 1 except that iodomethane was replaced with octyl bromide, the desired cellulose derivative (P-4, the degree of substitution, the molecular weight and the glass transition temperature are described in Table 1) was obtained as a white powder (115 g).

### Synthetic Example 5

### Synthesis of P-5

100 g of cellulose (pulp), 222 g of sodium hydroxide and 150 mL of water were placed into a 3 L small-scale type autoclave (manufactured by TAIATSU TECHNO CORPORATION), purged with nitrogen, and followed by stirring at 45° C. for 1 hour. Continuously, 150 mL of toluene was added and the mixture was cooled in the dry ice/methanol bath to −20° C. with slowly stirring, 358 g of ethyl chloride and 53 mL of octyl bromide were added, and sealed, followed by stirring at 120° C. for 12 hours. After the temperature was cooled to room temperature, 4 L of water was added with a vigorous stirring, neutralized and filtered to obtain a light gray solid. The obtained light gray solid was re-dispersed and washed with 2 L of hot water, and washed. This operation was repeated three times to obtain a white solid. The obtained white solid was separated by suction filtration, and dried under vacuum at 100° C. for 6 hours to obtain the desired cellulose derivative (P-5, the degree of substitution, the molecular weight and the glass transition temperature are described in Table 1) as a white powder (113 g).

### Synthetic Example 6

### Synthesis of P-6

In the same manner as in Synthetic Example 1 except that iodomethane was replaced with 2-ethylhexyl bromide, the desired cellulose derivative (P-6, the degree of substitution, the molecular weight and the glass transition temperature are described in Table 1) was obtained as a white powder (101 g).

### Synthetic Example 7

### Synthesis of P-7

In the same manner as in Synthetic Example 1 except that ethylcellulose was replaced with methylcellulose (manufactured by Shin-etsu Chemical, Co., Ltd., trademark: SM-15, the degree of methoxy substitution 1.8), and iodomethane was replaced with 2-ethylhexyl bromide, the desired cellulose derivative (P-7, the degree of substitution, the molecular weight and the glass transition temperature are described in Table 1) was obtained as a white powder (80 g).

### Synthetic Example 8

### Synthesis of P-8

In the same manner as in Synthetic Example 7 except that the amount of 2-ethylhexyl bromide added was changed from 3 mol equivalent to 6 mol equivalent, the desired cellulose derivative (P-8, the degree of substitution, the molecular weight and the glass transition temperature are described in Table 1) was obtained as an off-white solid (92 g).

### Synthetic Example 9

### Synthesis of P-9

In the same manner as in Synthetic Example 1 except that iodomethane was replaced with dodecyl bromide, and the amount added was changed from 3 mol equivalent to 1 mol equivalent, the desired cellulose derivative (P-9, the degree of substitution, the molecular weight and the glass transition temperature are described in Table 1) was obtained as a white powder (130 g).

### Synthetic Example 10

### Synthesis of P-10

In the same manner as in Synthetic Example 1 except that iodomethane was replaced with octadecyl bromide, and the amount added was changed from 3 mol equivalent to 1 mol equivalent, the desired cellulose derivative (P-10, the degree of substitution, the molecular weight and the glass transition temperature are described in Table 1) was obtained as a white powder (132 g).

### Synthetic Example of Comparative Compound

### Synthesis of H-3

50 g of powder cellulose (manufactured by NIPPON PAPER CHEMICALS CO., LTD, trademark: KC Flock W-50) and 150 mL of 50% aqueous sodium hydroxide solution were placed into a 5 L three-neck flask equipped with a mechanical stirrer, a thermocouple, a cooling tube and a drop lot, and followed by stirring at 45° C. for 1 hour. 446 mL of iodoethane (18 mol equivalent based on the glucopyranose unit) and 638 mL of benzyl chloride (18 mol equivalent based on the glucopyranose unit) were added, and followed by stirring at the external temperature of 110° C. for 5 hours. After the temperature was cooled to room temperature, an off-white solid was obtained by vigorously stirring in 4 L of methanol. The obtained off-white solid was re-dispersed and washed with 2 L of methanol. This operation was repeated three times to obtain a white solid. The obtained white solid was separated by suction filtration, and dried under vacuum at 100° C. for 6 hours to obtain a desired comparative compound (H-3, the degree of substitution, the molecular weight and the glass transition temperature are described in Table 1) as a white powder (98 g).

Further, with respect to the compounds obtained in the above, the kind of functional group substituted with the hydroxyl group contained in cellulose (hydroxyl groups at X², X³ and X⁶ positions), and DS_{A}, DS_{B} and DS_{C} were observed and determined by ¹H-NMR by using the method described in Cellulose Communication 6, 73-79(1999).

<Measurement of Physical Properties of Cellulose Derivatives>

With respect to the obtained cellulose derivatives, the number average molecular weight (Mn), weight average molecular weight (Mw), molecular weight distribution (MWD) and glass transition temperature (Tg) are described in Table 1. Further, the measurement method thereof will be described below.

[Molecular Weight and Molecular Weight Distribution]

The number average molecular weight (Mn), the weight average molecular weight (Mw) and the molecular weight distribution (MWD) were measured by using a gel permeation chromatography (GPC). Particularly, N-methypyrrolidone was used as a solvent, a polystyrene gel was used, and the number average molecular weight (Mn), the weight average molecular weight (Mw) and the molecular weight distribution (MWD) were obtained by using a reduced molecular weight calibration curve previously obtained from a standard monodispersion polystyrene constitution curve. As the GPC device, HLC-8220 GPC (manufactured by Toso, Co., Ltd.) was used.

[Glass Transition Temperature]

The glass transition temperature was measured by using the differential scanning calorimeter (Product No.: DSC6200, manufactured by Seiko Electronics, Co., Ltd.) while increasing the temperature at the rate of 10° C./min.

### Example 1

### Manufacturing of the Molded Body Formed of the Cellulose Derivative

[Manufacturing of Test Piece]

The cellulose derivative (P-1) obtained as described above was provided into the injection molding apparatus (manufactured by Imoto Seisakusho, Co., Ltd., semi-automatical injection molding apparatus), and molded into a test piece for multipurposes (impact test piece and bending test piece) having a size of 4×10×80 mm under the condition of the molding temperature (cylinder temperature) as described in Table 1, the mold temperature of 40° C. and the injection pressure of 1.5 kgf/cm².

### Examples 2 to 10, and Comparative Examples 1 to 4

In the same manner as in Example 1, test pieces were manufactured by molding the cellulose derivatives (P-2) to (P-10), (H-3), and the cellulose derivatives (H-1) (manufactured by Wako Pure Chemical Industries: methylcellulose, the degree of methyl substitution 1.8), (H-2) (manufactured by Dow Chemical, Co., Ltd.: ethylcellulose, the degree of ethyl substitution 2.6) and (H-4) (manufactured by Aldrich, Co., Ltd.: hydroxypropyl methylcellulose, the degree of methyl substitution 2.1 and the degree of hydroxypropyl substitution 0.8) as comparative compounds under the molding conditions of Table 1.

<Measurement of Physical Properties of Test Pieces>

With respect to the obtained test pieces, the Charpy impact strength, bending elasticity and bending strength were measured by the following method. The results are described in Table 1.

[Charpy Impact Strength]

In accordance with ISO 179, the test pieces molded by injection molding were provided with a notch having the front end of 0.25±0.05 mm and an incident angle of 45±0.5°, and controlled under the conditions of 30° C.±2° C. and 50%±15% RH for 48 hours or more, and then the impact strength was measured by the Charpy impact tester with the edge wise.

[Bending Elasticity and Bending Strength]

In accordance with ISO 178, bending elasticity was measured by controlling the test pieces molded by injection molding under the conditions of 23° C.±2° C. and 50%±5% RH for 48 hours or more, and performing the bending test by Instron (manufactured by Toyo Seiki,

Co., Ltd., Strograph V50) under the conditions of a distance between points of 64 mm and a test rate of 2 mm/min. Further, the maximum stress during the test was measured as bending strength.

TABLE 1

| | | Residual | Aliphatic oxy | | Aliphatic oxy | | | | | | molding | | | |
|---|---|---|---|---|---|---|---|---|---|---|---|---|---|---|
| | | hydroxyl | group | | group | | Difference | | | | temper- | impact | bending | bending |
| | Com- | group | (-OR1) | | (-OR2) | | in carbon | Mn | Mw | Tg | ature | strength | elasticity | strength |
| | pound | DS_{A} | R1 | DS_{B} | R2 | DS_{C} | number | (k) | (k) | (° C.) | (° C.) | (kJ/m²) | (GPa) | (MPa) |
| Example 1 | P-1 | 0.3 | Ethyl | 2.6 | Methyl | 0.1 | 1 | 51 | 212 | 129 | 240 | 17 | 2.6 | 70 |
| Example 2 | P-2 | 0.2 | Ethyl | 2.6 | Butyl | 0.2 | 2 | 64 | 198 | 121 | 210 | 17 | 2.1 | 69 |
| Example 3 | P-3 | 0.2 | Ethyl | 2.6 | Heptyl | 0.2 | 5 | 59 | 190 | 119 | 210 | 19 | 2.0 | 65 |
| Example 4 | P-4 | 0.3 | Ethyl | 2.6 | Octyl | 0.1 | 6 | 55 | 170 | 121 | 200 | >25 | 2.8 | 74 |
| Example 5 | P-5 | 0.1 | Ethyl | 2.6 | Octyl | 0.3 | 6 | 56 | 161 | 111 | 190 | >25 | 2.7 | 72 |
| Example 6 | P-6 | 0.3 | Ethyl | 2.6 | 2-Ethylhexyl | 0.1 | 6 | 53 | 170 | 125 | 200 | 24 | 2.9 | 75 |
| Example 7 | P-7 | 0.8 | Methyl | 1.8 | 2-Ethylhexyl | 0.4 | 7 | 66 | 230 | 110 | 210 | 16 | 1.6 | 57 |
| Example 8 | P-8 | 0.1 | Methyl | 2.3 | 2-Ethylhexyl | 0.6 | 7 | 61 | 221 | 105 | 190 | 17 | 1.4 | 50 |
| Example 9 | P-9 | 0.35 | Ethyl | 2.6 | Dodecyl | 0.05 | 10 | 54 | 170 | 105 | 170 | 17 | 2.1 | 69 |
| Example 10 | P-10 | 0.38 | Ethyl | 2.6 | Octadecyl | 0.02 | 16 | 61 | 204 | 104 | 160 | 17 | 2.0 | 65 |
| Compartive | H-1 | 1.2 | Methyl | 1.8 | — | 0 | — | 70 | 210 | 3 | 1 | 1 | 1 | 1 |
| Example 1 | | | | | | | | | | | | | | |
| Compartive | H-2 | 0.4 | Ethyl | 2.6 | — | 0 | — | 37 | 151 | 139 | 240 | 14 | 1.4 | 55 |
| Example 2 | | | | | | | | | | | | | | |
| Compartive | H-3 | 0.6 | Ethyl | 1.2 | Benzyl | 1.2 | 5 | 25 | 121 | 3 | 250 | 4 | 3.1 | 70 |
| Example 3 | | | | | | | | | | | | | | |
| Compartive | H-4 | 0.1 | Methyl | 2.1 | Hydroxypropyl | 0.8 | — | 153 | 1098 | 3 | 260 | 2 | 2 | 2 |
| Example 4 | | | | | | | | | | | | | | |

DS_{A}: Degree of hydroxyl group, DS_{B}: Substitution degree of ether (-OR1), DSC: Substitution degree of ether (-OR2)
1: Since the thermoplasticity was not exhibited and thermal molding could not be performed, the evaluation could not be accomplished.
2: Since the thermoplasticity was exhibited, but fluidity during thermal molding was very low, and the regulated test pieces could not be manufactured, the evaluation could not be accomplished.
3: The apparent Tg during measurement of DSC was not observed.

As shown in the results of Table 1, it can be seen that methylcellulose (Comparative Example 1) does not have thermoplasticity, while further introduction of the aliphatic oxy group (—OR2) having an aliphatic group other than a methyl group imparts thermoplasticity to make it moldable, and ensures high impact strength (Examples 7 and 8). Further, it can be seen that ethylcellulose (Comparative Example 2) has low bending elasticity and bending strength, while further introduction of the aliphatic oxy group (—OR2) having an aliphatic group other than an ethyl group provides enhanced bending elasticity and bending strength (Examples 1 to 6, 9 and 10). In addition, since the molding temperature can be decreased, an easy-to-mold property may be provided. In the case where the aliphatic oxy group contains an aromatic group (Comparative Example 3), bending elasticity and strength are improved, but impact strength is significantly reduced. Therefore, it is apparently preferable that the aliphatic oxy group does not contain an aromatic group. Moreover, when the aliphatic oxy group has a hydrogen bonding substituent such as the hydroxypropyl group, the molding temperature is very high, leading to poor thermal moldability (Comparative Example 4).

From the above, it can be seen that the molded body using the cellulose derivative of the present invention has high toughness (impact strength) and rigidity (bending elasticity and bending strength). That is, according to the cellulose derivative of the present invention, an unexpected effect of ensuring of both toughness and rigidity as well as ensuring of thermoplasticity can be obtained.

According to a cellulose resin composition for melt molding of the present invention, it is possible to obtain a molded body that has excellent toughness (impact strength) and rigidity (bending elasticity, and bending strength) while maintaining good thermoplasticity. Further, since the cellulose derivative in the present invention can be synthesized in one pot from cellulose, it is possible to provide a material for melt shaping having the aforementioned excellent performance at a low cost. In addition, since the derivative is a plant-derived resin, the derivative is a material that can contribute to preventing global warming, and can replace a conventional petroleum-derived resin. Therefore, the cellulose resin composition for melt shaping of the present invention may be suitably used, for example, as a case for electric and electronic devices.

The present invention has been described in detail with reference to the exemplary embodiments, but it is obvious to a person having ordinary skill in the art that various modification or alteration may be made without departing from the spirit and scope of the present invention.

This application claims priority from Japanese Patent Application No. 2009-154076 filed on Jun. 29, 2009, the disclosure of which is incorporated herein by reference in its entirety.

1. A cellulose resin composition for melt molding, comprising:
a cellulose derivative having two or more kinds of aliphatic oxy groups having different carbon numbers,
wherein aliphatic groups of the aliphatic oxy groups may be unsubstituted or substituted, and
a difference in carbon number between the aliphatic oxy group having the largest carbon number and the aliphatic oxy group having the smallest carbon number is 1 to 18.

2. The cellulose resin composition according to claim 1,
wherein the cellulose derivative has two kinds of aliphatic oxy groups,
the two kinds of the aliphatic oxy groups are represented by —OR1 and —OR2, respectively,
R1 and R2 represent an unsubstituted or substituted group, and a difference in carbon number between R1 and R2 is 1 to 18.

3. The cellulose resin composition according to claim 2,
wherein the degree of substitution DS_{B} of the aliphatic oxy group which is represented as —OR1 is 1.5 to 2.8,
the degree of substitution DS_{C} of the aliphatic oxy group which is represented as —OR2 is 0.1 to 0.8, and
wherein DS_{B} represents the number of aliphatic oxy group which is represented as —OR1 with respect to the hydroxyl groups at the 2-, 3-, and 6-positions of a β-glucose ring in the repeating unit, and
DS_{C} represents the number of the aliphatic oxy group which is represented as —OR2 with respect to the hydroxyl groups at the 2-, 3-, and 6-positions of a cellulose structure of the β-glucose ring in the repeating unit.

4. The cellulose resin composition according to claim 1,
wherein the difference in carbon number is 1 to 10.

5. The cellulose resin composition according to claim 1,
wherein the difference in carbon number is 5 to 7.

6. The cellulose resin composition according to claim 1,
wherein the aliphatic oxy group does not contain a hydrogen bonding group and an aromatic group.

7. The cellulose resin composition according to claim 2,
wherein the carbon number of R1 is 1 to 6, and the carbon number of R2 is 1 to 18.

8. The cellulose resin composition according to claim 2,
wherein R1 is an ethyl group.

9. The cellulose resin composition according to claim 2,
wherein R1 is an ethyl group, and
R2 is an octyl group.

10. A molded body comprising the cellulose resin composition according to claim 1.

11. A case for electric and electronic devices comprising the molded body according to claim 10.

12. A cellulose derivative comprising an ethoxy group and an octyloxy group.

13. A method for preparing a cellulose derivative having two or more kinds of aliphatic oxy groups having different carbon numbers, wherein aliphatic groups of the aliphatic oxy groups may be unsubstituted or substituted, and a difference in carbon number between the aliphatic oxy group having the largest carbon number and the aliphatic oxy group having the smallest carbon number is 1 to 18, the method comprising:
reacting a cellulose and two or more kinds of halogenated aliphatic compounds having different carbon numbers in the presence of a base.

14. A method for manufacturing a molded body, comprising:
heating and molding the cellulose resin composition according to claim 1.

15. The cellulose resin composition according to claim 2, the carbon number of R1 is smaller than that of R2.

16. A method for manufacturing a molded body, comprising:
heating and molding the cellulose derivative according to claim 12.
